(19) United States
(12) Patent Application Publication
(10) Pub. No.: US 2016/0333468 A1
(43) Pub. Date: Nov. 17, 2016

(54) HYDROPHOBIC STRUCTURE AND METHOD FOR MAKING SAME

(71) Applicant: FIH (HONG KONG) LIMITED, Kowloon (HK)

(72) Inventors: YU-TSAI WANG, New Taipei (TW); YI-TING YEH, New Taipei (TW)

(21) Appl. No.: 14/754,319

(22) Filed: Jun. 29, 2015

(30) Foreign Application Priority Data
May 11, 2015 (CN) 201510235363.8

(51) Int. Cl. C23C 14/58; C23C 2/26; C09D 5/00

(52) U.S. Cl. CPC C23C 14/5873; C09D 5/00; C23C 2/26

(57) ABSTRACT

A hydrophobic structure includes a base and a hydrophobic layer. The base defines a plurality of gaps. The hydrophobic layer is formed on an outer surface of the base and inner surfaces of the base surrounding each gap. The outer surface is defined as one side surface of the base, each inner surface is defined as a surface perpendicular to the outer surface and positioned at one side of each gap

### FIELD

The subject matter herein generally relates to a hydrophobic structure, and particularly to a hydrophobic structure used in electronic devices and a method for making the hydrophobic structure.

### BACKGROUND

Small holes and gaps are commonly defined in a housing of an electronic device to obtain a special appearance such as an image development effect or a metal integration effect. However, the above-mentioned small holes or gaps need to be processed to be waterproof and dustproof while using the electronic device. In a typical way, glue is filled into the small holes or gaps to obtain the waterproof function. However, during filling the glue, bad products may be easily generated due to phenomenon of insufficient filling, overflow, bubble and so on.

### BRIEF DESCRIPTION OF THE FIGURES

Implementations of the present technology will now be described, by way of example only, with reference to the attached figures.

FIG. 1 is an isometric view of a hydrophobic structure, according to an exemplary embodiment.

FIG. 2 is a cross-sectional view of the hydrophobic structure along line II-II of FIG. 1.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

The term “comprising” when utilized, means “including, but not necessarily limited to”; it specifically indicates open-ended inclusion or membership in the so-described combination, group, series and the like.

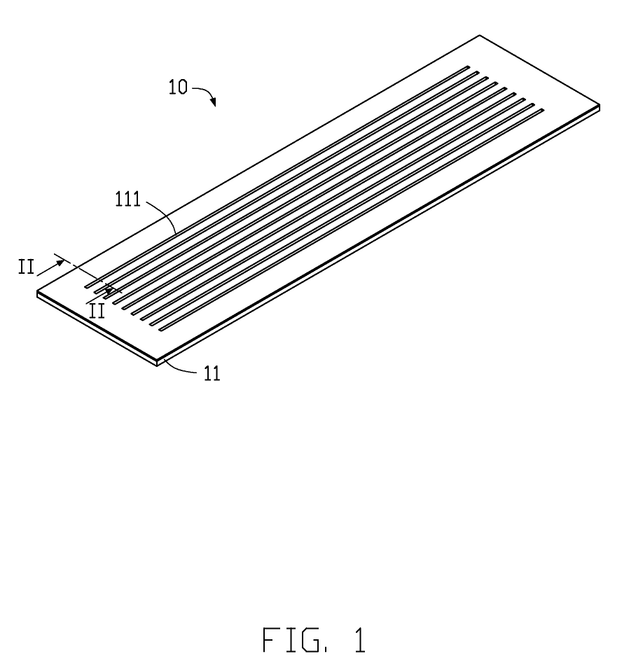

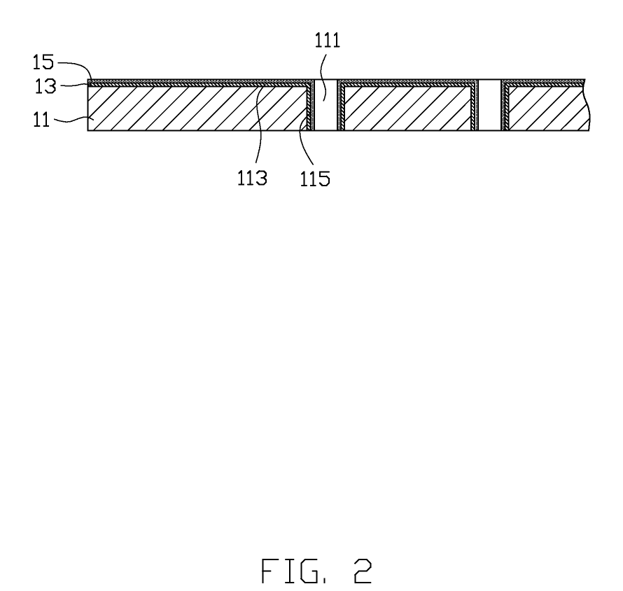

FIG. 1 illustrates a hydrophobic structure 10 according to an exemplary embodiment. The hydrophobic structure 10 can be a housing of a mobile phone, a personal digital assistant, or a panel computer. FIG. 2 illustrates that the hydrophobic structure 10 includes a base 11, a decorating layer 13 formed on the base 11, and a hydrophobic layer 13 formed on the decorating layer 13.

At least one gap 111 is defined in the base 111. In this exemplary embodiment, there are nine gaps 111. The gaps 111 are communicating through two opposite surfaces of the base 11 or not. In this embodiment, the gaps 111 are communicating through the opposite surfaces of the base 11. A width of each gap 111 is about 0.01 mm-0.07 mm. In this embodiment, the width of each gap 111 is about 0.03 mm. A distance between every two adjacent gaps 111 is about 0.8 mm-1 mm.

In other embodiment, the gaps 111 may be a plurality of small holes are defined in the base 11 communicating through the opposite surfaces of the base 11 or not. An aperture of each small hole is about 0.01 mm-0.08 mm.

The base 11 is made of metal, plastic, or fiber. The metal can be selected from a group consisting of stainless steel, aluminum alloy, and titanium alloy. The plastic can be selected from a group consisting of polycarbonate (PC), polyamide (PA), combination of polycarbonate and glass fiber, combination of PA and glass fiber, polybutylene terephthalate (PBT), polyether ether ketone (PEEK), and their modified materials. The fiber can be selected from a group consisting of carbon fiber, glass fiber, and aramid fiber. In this embodiment, the base 11 is made of aluminum alloy.

The decorating layer 13 is formed on an outer surface 113 of the base 11 and inner surfaces 115 of the base 11 surrounding each gap 111 so that the base 11 can show a better appearance. The outer surface 113 is defined as one side surface of the base 11. Each inner surface 115 is defined as a surface perpendicular to the outer surface 113 and positioned at one side of each gap 111. A thickness of the decorating layer 13 is about 10 nm-100 nm.

The hydrophobic layer 15 is formed on a surface of the decorating layer 13. In other embodiment, the decorating layer 13 can be omitted, and the hydrophobic layer 15 can be directly formed on the outer surface 113 of the base 11 and the inner surfaces 115 of the base 11 surrounding each gap 111. The hydrophobic layer 15 is configured for reducing chemical energy of the outer surface 113 of the base 11 and the inner surfaces 115 of the base 11 surrounding each gap 111 thereby increasing a contact angles between liquid and the outer surface 113 of the base 11 and the inner surfaces 115 of the base 11 surrounding each gap 111 and reducing contact areas between the liquid and the outer surface 113 of the base 11 and the inner surfaces 115 of the base 11 surrounding each gap 111. Therefore, the outer surface 113 of the base 11 and the inner surfaces 115 of the base 11 surrounding each gap 111 generate a water repelling effect. As such, water cannot easily infiltrate into the gaps 111 and the hydrophobic structure 10 can obtain a waterproof effect. The hydrophobic layer 15 is made of hydrophobic material such as fluoride hydrophobic material.

An exemplary method for making the hydrophobic structure 10 can include the following steps.

The base 11 having three-dimensions is provided. The base 11 is made of metal, plastic, or fiber. The metal can be selected from a group consisting of stainless steel, aluminum alloy, and titanium alloy. The plastic can be selected from a group consisting of polycarbonate (PC), polyamide (PA), combination of polycarbonate and glass fiber, combination of PA and glass fiber, polybutylene terephthalate (PBT), polyether ether ketone (PEEK), and their modified materials. The fiber can be selected from a group consisting of carbon fiber, glass fiber, and aramid fiber. In this exemplary embodiment, the base 11 is made of aluminum alloy. A shape of the base 11 can be changed according to requirements.

At least one gap 111 is formed on a surface of the base 11 by cutting the surface of the base 11. In this exemplary embodiment, there are nine gaps 111 formed on the surface of the base 11. In this embodiment, the plurality of gaps 111 are formed on the surface of the base 11 by laser cutting or computer numerical control (CNC). The gaps 111 are communicating through two opposite surfaces of the base 11 or not. A width of each gap 111 is about 0.01 mm-0.07 mm. In this embodiment, the width of each gap 111 is about 0.03 mm. A distance between every two adjacent gaps 111 is about 0.8 mm-1 mm.

In other embodiment, the gaps 111 may be a plurality of small holes formed on the surface of the base 11 by laser cutting, CNC, or etching. An aperture of each small hole is about 0.01 mm-0.08 mm.

A decorating layer 13 is formed on the surface of the base 11 by surface treatment. The decorating layer 13 can be formed by physical vapor deposition (PVD), anodic oxidation, paint and so on so that the base 11 can show a better appearance. In this embodiment, the decorating layer 13 is formed by anodic oxidation. A thickness of the decorating layer 13 is about 10 nm-100 nm.

A hydrophobic layer 15 is formed on a surface of the decorating layer 13. In this embodiment, the above-mentioned base 11 formed with the decorating layer 13 is immersed into hydrophobic coating so that each surface of the base 11 is dipped in the hydrophobic coating. The base 11 dipped in the hydrophobic coating is moved outside to be naturally dried, and then braked under a temperature of about 100-180 to solidify the hydrophobic coating and form the hydrophobic layer 15, thereby obtaining the hydrophobic structure 10. A thickness of the hydrophobic layer 15 is about 10 nm-100 nm. In other embodiment, the hydrophobic layer 15 can be formed by spraying or coating.

In other embodiment, the gaps 111 and the small holes can be formed after forming the decorating layer 13.

The hydrophobic structure 10 makes the gaps 111 or small holes defined in the base 11 obtain a better hydrophobic effect by the hydrophobic layer 15 formed on the base 11. The method of making the hydrophobic structure 10 is relative simple and have a relative lower cost so that the hydrophobic structure 10 can be better applied in various electronic device.

It is to be understood, however, that even through numerous characteristics and advantages of the present disclosure have been set forth in the foregoing description, together with details of assembly and function, the disclosure is illustrative only, and changes may be made in detail, especially in the matters of shape, size, and arrangement of parts within the principles of the disclosure to the full extent indicated by the broad general meaning of the terms in which the appended claims are expressed.

What is claimed is:

1. A hydrophobic structure comprising:
a base having a plurality of gaps; and
a hydrophobic layer formed on an outer surface of the base and inner surfaces of the base surrounding each gap; wherein the outer surface is defined as one side surface of the base, each inner surface is defined as a surface perpendicular to the outer surface and positioned at one side of each gap.

2. The hydrophobic structure of claim 1, wherein the hydrophobic layer is made of hydrophobic material and has a thickness of about 10 nm-100 nm.

3. The hydrophobic structure of claim 1, wherein a width of each gap is about 0.01 mm-0.07 mm.

4. The hydrophobic structure of claim 1, wherein the base is made of one of metal, plastic, and fiber; the metal is selected from a group consisting of stainless steel, taluminum alloy, and titanium alloy; the plastic is selected from a group consisting of polycarbonate, polyamide, combination of polycarbonate and glass fiber, combination of PA and glass fiber, polybutylene terephthalate, polyether ether ketone, and their modified materials; the fiber is selected from a group consisting of carbon fiber, glass fiber, and aramid fiber.

5. The hydrophobic structure of claim 1, further comprising a decorating layer formed between the base and the hydrophobic layer.

6. The hydrophobic structure of claim 5, wherein a thickness of the decorating layer is about 10 nm-100 nm.

7. A hydrophobic structure, comprising:
a base defines a plurality of gaps; and
a hydrophobic layer formed on an outer surface of the base and inner surfaces of the base surrounding each gap, wherein the outer surface is defined as one side surface of the base, each inner surface is defined as a surface perpendicular to the outer surface and positioned at one side of each gap; the hydrophobic layer increases contact angles between liquid and the outer surface of the base and the inner surfaces of the base surrounding each gap and reduces a contact area between the liquid and the outer surface of the base and the inner surfaces of the base surrounding each gap; inner.

8. The hydrophobic structure of claim 7, wherein the hydrophobic layer is made of hydrophobic material and has a thickness of about 10 nm-100 nm.

9. The hydrophobic structure of claim 7, wherein a width of each gap is about 0.01 mm-0.07 mm.

10. A method of making a hydrophobic structure comprising:
providing a base;
cutting the base to form a plurality of gaps on a surface of the base; and
forming a hydrophobic layer on an outer surface of the base and inner surfaces of the base surrounding each gap.

11. The method of claim 10, wherein the step of forming the hydrophobic layer comprising:
immersing the base defined with gaps into hydrophobic coating;
moving outside the base dipped in the hydrophobic coating to be naturally dried; and
braking the base under a temperature of about 100° C.-180 to solidify the hydrophobic coating and form the hydrophobic layer.

12. The method of claim 10, further comprising forming a decorating layer on the outer surface of the base and the inner surface of the base surrounding each gap by surface treatment of physical vapor deposition (PVD), anodic oxidation and paint before forming the forming the hydrophobic layer.
